(19) United States
(12) Patent Application Publication
(10) Pub. No.: US 2025/0274107 A1
(43) Pub. Date: Aug. 28, 2025

(54) ADAPTIVE VARIABLE CYCLE ELECTROLYSIS CONTROL DEVICE

(71) Applicant: Micro Hydrogen Inc., Wichita, KS (US)

(72) Inventor: Qiang YAN, Wichita, KS (US)

(21) Appl. No.: 19/047,612

(22) Filed: Feb. 6, 2025

(30) Foreign Application Priority Data
Feb. 22, 2024 (CN) 202410195283.3

(51) Int. Cl. H03K 3/017; C25B 9/65; C25B 15/02

(52) U.S. Cl. CPC H03K 3/017; C25B 9/65; C25B 15/02

(57) ABSTRACT

An adaptive variable cycle electrolysis control device and control method and application are provided. The adaptive variable cycle power control device is connected in series between electrolytic cell and power supply during electrochemical electrolysis, comprising a voltage-relief circuit, a pulse width modulation and drive circuit, and a constant-current source control circuit. The output end of the step-down circuit is connected to input end of the constant-current source control circuit. Each output end of the constant-current source control circuit is connected to each electrode in the electrolytic cell in a one-to-one correspondence. Each electrode has a contact and is connected in series with each electrode through a contact control switch (Gn). The pulse width modulation and drive circuit respectively controls the on and off of the step-down circuit and the constant-current source circuit.

### CROSS-REFERENCE TO RELATED APPLICATION

The subject application claims priority on Chinese Patent Application No. CN202410195283.3 filed on Feb. 22, 2024 in China. The contents and subject matter of the Chinese priority application is incorporated herein by reference.

### TECHNICAL FIELD

The present invention relates to electrolysis technology by electrochemical methods, particularly, an adaptive variable cycle electrolysis control device and its control method and application.

### BACKGROUND ART

Hydrogen and oxygen are both important industrial raw materials, while in addition, hydrogen has a high combustion value and is a type of completely clean energy, and hydrogen energy is becoming more and more widely used and loved by people.

Existing hydrogen production methods include water electrolysis, fossil fuel reforming, decomposition, photolysis, etc. To date, water electrolysis accounts for only 4 to 5 percent of the world's hydrogen production, and more than 95 percent of hydrogen is obtained through fossil fuel reforming. The production process inevitably emits CO₂, while water electrolysis technology using grid-independently utilizes clean energy, it can achieve zero CO₂ emissions and significantly reduce the cost of hydrogen production. However, hydrogen production by water electrolysis requires ionization of water molecules into hydrogen and oxygen, which are precipitated at the cathode and anode, respectively, through electrochemical processes under the action of relatively stable direct current. Depending on the diaphragm, it can be divided into alkaline water electrolysis, proton exchange membrane water electrolysis, and solid oxide water electrolysis. Usually, the electrolyzer is set up with a number of electrolytic chambers (electrode plates) connected in series, the number of electrodes (electrolytic chambers) connected in series is set according to the DC voltage value of the power supply, then the electrode size is set according to the current value of the power supply, and when the electrode size is determined, the electrolyzer will become a constant current source. The total voltage in the electrolyzer is the sum of the voltages of the electrodes (electrolytic chambers), and the total current is the same as that of the electrodes (electrolytic chambers). Although in recent years there has been the use of renewable energy, such as wind energy, solar energy, for hydrogen and oxygen production, due to the water electrolysis of hydrogen and oxygen production on the stability of the power supply requirements are very high, while the wind and solar energy, but all have a large fluctuation in energy, and not only voltage fluctuations in the range of large current fluctuations is even greater, especially in the use of wind generators as a stand-alone hydrogen production power supply, most of the state, wind power Generator output power is far below the rated power, the current drop rate is higher than the voltage drop rate, if there is no power control measures, as a constant current source of electrolytic devices will quickly drag down the wind turbine speed, in turn, the speed of the wind turbine power output is reduced on the basis of the original further reduced. So, at the end of the day, hydrogen production from renewable energy sources without grid power support is still a serious challenge.

US Patent Application Publication US20110155583A1 solves the fluctuating power supply concept by connecting electrolyzers in series and parallel, in this publication, an electrolyzer is accessed or cut out in series through voltage fluctuation, and an electrolyzer is accessed or cut out when the current fluctuates to cope with the challenge of power supply fluctuation. Firstly, electrolyzers in series access to in or cutting out will cause a huge change in the voltage of individual electrodes, and 50% of the voltage change is beyond the safe range of electrode voltage, and at the same time, no matter whether it is simple to connect electrolyzers in parallel or to cut out electrolyzers, it will not be possible to keep the power supply in the state of a constant-current source, and supply power to the electrolyzers which are in the state of being switched on, and therefore it is practically difficult to be applied.

Chinese utility model patents CN201720255416.7 and CN201820120226.9 disclose electrolysis devices which, on the other hand, split the device as disclosed in the U.S. publication US20110155583A1 into series access to four groups of electrolysis chamber groups (equivalent to electrolyzers) and parallel access to electrolyzers, and control access to and cut out of the series four electrolysis chambers with contact switches to solve the problem of Voltage fluctuation, and parallel electrolyzer to solve the current fluctuation. Essentially the same as US20110155583A1, they just increase two electrolyzers to four electrolytic chamber groups (equivalent to electrolyzers), and the result is just to reduce 50% voltage fluctuation to 25%, but the design still does not understand the power characteristics of renewable energy sources such as wind and solar, i.e., it is not a constant current source when the fluctuating power supply is lower than the rated power, and it cannot simply based on the voltage change. Access, cut out the electrolytic chamber group, or simply according to the power supply current changes in parallel access or cut out the electrolyzers.

In Chinese patent application CN202010788030.9, a control circuit is connected in parallel in each electrode. It is well known, parallel connection is to divide the current problem, and series connection is to divide the voltage problem. As the electrodes connected in series and the process requirements for the connection of the electrolyzer, each electrode can no longer be independently connected in parallel connecting to a control circuit, and even if a control circuit can be connected in parallel to each electrode, it is not possible to make the renewable energy source maintain power supply for the electrolyzer in the state of a constant-current source when it is less than the rated power, and therefore cannot be practically applied.

Chinese patent applications CN2020102878073, CN202010780544X, CN2020107929245, CN2020108234224 and CN2021106689126, respectively, disclose accessing and cutting or out a certain number of electrodes one by one according to the fluctuation of voltage, the accessing or cutting in or cutting out a certain number of electrolyzers according to the change of current of the fluctuating power supply to circumvent the effect of power supply fluctuation on the electrolyzer. However, the above five references also ignored the electrolyzer that is a constant current source, and when the fluctuation of the power supply is lower than the rated power, the power supply output is not a constant current source, when the power supply power is lower than the rated power, the wind turbine will be dragged down by the electrolyzer of the constant current source, so that the power supply and electrodes in the on state of the power mismatch still exists.

Given all of the above, either the failure to fully understand that the output current of a very volatile power supply is not a constant-current source when it is below rated power, but rather exhibits a decline in relation to the square of the rated current, and that the power supply's current will be much less than the rated current, or the failure to understand that once the electrodes have been sized the electrolyzer is a constant-current source independent of the power supplied by the external power source.

### SUMMARY OF THE INVENTION

It is an object of the present invention to remedy the above mentioned deficiencies of the prior art. The present invention provides an adaptive variable cycle electrolysis control device and its control method and application.

The technical solution of the present invention is as follows.

An adaptive variable cycle electrolysis control device, characterized in that said adaptive variable cycle power control device is connected in series between electrolyzers and a power source during electrochemical electrolysis, comprising a voltage reduction circuit, a pulse width modulation and drive circuit, and a constant current source control circuit, the output of said voltage reduction circuit being connected to the input of said constant current source control circuit, the respective outputs of said constant current source control circuit and the respective electrodes in the electrolytic tank Each electrode has a contact and is connected in series with each electrode through a contact control switch (Gn), and said pulse width modulation and drive circuit controls the turn-on and turn-off of the buck circuit and the constant current source circuit respectively.

Moreover, each electrode in said electrolyzer has a contact, each output of the constant current source control circuit is connected in series through a contact control switch (Gn) and an electrode correspondingly, respectively, and said power source is a renewable energy power supply.

Moreover, the number quantity of electrodes of said electrolyzer is set according to the maximum output voltage value of the fluctuating power supply, the first electrode is connected to the negative pole of the power supply, the output terminal of said constant current source control circuit is one less than the number of electrodes, and the nth output terminal of the constant current source is connected to the nth electrode.

The present invention also provides a control method of the above-described adaptive variable cycle electrolysis control device, which is divided into two control methods according to different states.

The steps of the first control method of the adaptive variable cycle electrolysis control device are: the ratio of the voltage drop of said voltage reduction circuit is the same as the ratio of the rated current of the power supply of the renewable energy source to the instantaneous current, and the voltage drop value is adjusted by the duty cycle of the voltage reduction circuit; the constant power control circuit in which each output terminal and contact determines the contact control switch (Gn) to be on or off according to the ratio of the instantaneous power value and the rated power value of the renewable energy power supply, and the on state of said contact control switch (Gn) is always on or always off.

The steps of the control method of the second adaptive variable cycle electrolysis control device are: when the chopper buck circuit contact control is in a normally conducting state, determining the turning on or off of Gn in the constant power control circuit according to the ratio of the instantaneous voltage value of the renewable energy supply power source to the rated voltage value; according to the ratio of the instantaneous current of the input power supply source and the rated current, making the constant power control circuit in the turning on state of the contacts in a transient turn-on and transient turn-off state, said transient turn-on and turn-off time ratio being determined according to the ratio of the instantaneous current of the renewable energy power supply and the rated current.

Moreover, in said pulse width modulation and driving circuit, the modulating wave frequency of the duty cycle is from 5 Hz to 50 Hz.

An electrolysis station comprising a plurality of sets of the aforementioned adaptive variable cycle electrolysis control devices connected in parallel.

The advantages and positive effects of the present invention are:

The present invention can be independent of the power grid, independently uses wind energy, solar energy or other energy fluctuation amplitude is very large clean energy as an independent power source, for electrochemical methods of electrolysis adaptive variable cycle electrolysis control device, and through the power supply changes in the law of the development of the corresponding control method, can effectively ensure that each electrode in the working state, not only are in the state of constant-current source of electrolysis, and are in a very narrow voltage fluctuation range

The present invention is an integrating innovation under the condition of fully understanding the power characteristics and electrolysis characteristics of wind and solar energy, which have very large energy fluctuations, and has high market value and industrial adaptability.

### BRIEF DESCRIPTION OF THE DRAWINGS

FIG. 1 is a schematic diagram of the principle of the adaptive variable cycle electrolysis control device in the present invention.

FIG. 2 is a schematic diagram of the duty cycle involved in the second control method in the present invention.

### DETAILED DESCRIPTION OF THE INVENTION

The specific control method and control logic of the present invention will be described in further detail below in conjunction with the specific embodiments and accompanying drawings.

An adaptive variable cycle electrolysis control device, connected in series between an electrolyzer and a power source, comprising a voltage reduction circuit, a pulse width modulation and drive circuit, and a constant current source control circuit, the output of said voltage reduction circuit being connected to the input of said constant current source control circuit, the respective outputs of the constant current source control circuit being connected to respective electrodes in the electrolyzer, the respective electrodes in the electrolyzer being provided with a contact, the respective outputs of the constant current source control circuit being connected in series by a contact control switch (Gn) and an electrode correspondingly, said power source being a renewable energy power supply, the pulse width modulation and drive circuit respectively controlling the electrolyzer and an electrode, and the pulse width modulation and drive circuit respectively controlling the electrolyzer and an electrode. Each output of the constant current source control circuit is connected in series with an electrode through a contact control switch (Gn), and said power source is a renewable energy power supply, and the pulse width modulation and driver circuits control the turn-on and turn-off of the buck circuit and the constant current source circuit respectively.

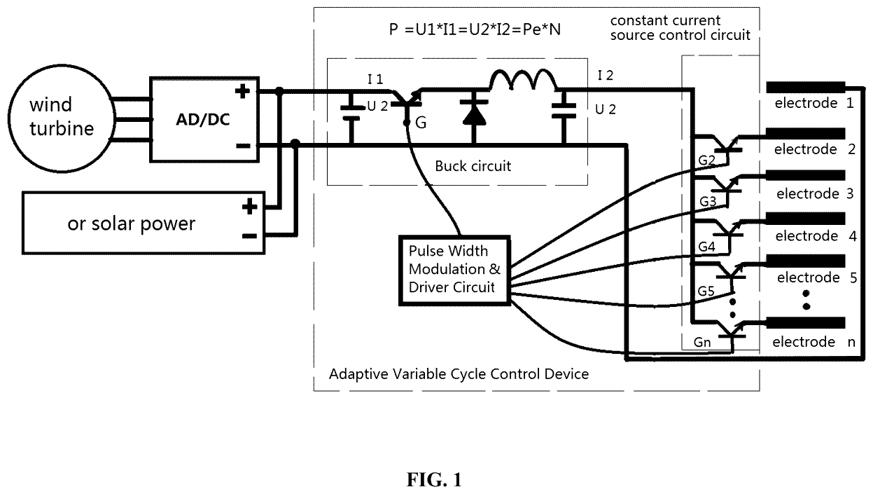

FIG. 1 is a schematic diagrammatic view of the principle of the adaptive variable cycle electrolysis control device, in which an adaptive variable cycle power control device is connected in series between a power source and an electrolyzer in an electrolyzer in a series manner, the control device consisting of three main control circuits, the first being a voltage reduction circuit, the second being a pulse width modulation and drive control circuit, and the third being a constant current source control circuit.

In the present invention, it does not change the basic principle of existing electrolysis, i.e., how to determine the electrode size, but the number of electrodes is set according to the highest voltage value of the fluctuating power supply.

In FIG. 1, the pulse width modulation drive circuit has two independent contact control outputs, which are fixedly connected to the control terminal G in the buck circuit 1 and to the N control switches Gn in the constant current source control circuit, and in the constant current source circuit, each output Gn is fixedly connected in series with each electrode (electrolysis chamber) with a contact, but is one less than the number of electrodes, the first electrode is connected to the negative pole of the power supply, and each electrode (electrolysis chamber) is connected in series with each other to form an electrolysis tank. The first electrode is connected to the negative pole of the power supply, and each electrode (electrolytic chamber) is connected in series with each other to form an electrolytic tank, which electrolytic tank and the adaptive variable-cycle control device together form an electrolytic device, and a plurality of sets of the above-mentioned adaptive variable-cycle electrolytic control devices are connected in parallel and can be applied in an electrolytic station.

Due to the unstable of new renewable energy and the characteristic of constant power is required at the load side, the control device of the present invention has two control methods and control logics.

The first control method and logic is to control the bucking ratio of the bucking circuit, the ratio of the bucking ratio and the power supply power supply rated current and transient current ratio is the same, and the bucking is realized by the duty cycle in the pulse width modulation circuit to realize the bucking of the circuit. Relative to the power supply, according to the principle of conservation of energy, the buck will not reduce the power, the ratio of the buck will increase the corresponding current multiplier, so that the power supply due to the wind speed (illuminance) to reduce the power supply caused by the power reduction caused by the power reduction of the current is compensated for by the buck and become a constant current source. At the same time, the pulse width modulation and drive circuit through the Gn, control the constant current source electrode on and off, this “on” and “off” in the constant on or constant off state. Gn off and on depends on the power supply rated power and transient power ratio. For example, when the transient power of the power supply is reduced to ⅛ of the rated power, ⅞ of the electrodes are disconnected from the power supply, and only ⅛ of the electrodes (electrolytic chamber) and the power supply are in the fully on state, and the electrodes which are in the fully on state, because of the voltage drop by a factor of 4, the current is also enlarged by a factor of 4, so that the current is in the state of constant-current source power supply, which is matched with the current of electrolytic cell, and the voltage is also reduced by a factor of 4, so that the current is in the state of constant-current source power supply, and the current of electrolytic tank is matched with the voltage. Because the voltage drops by 4 times, the final voltage is only ⅛ of the rated voltage and matches the number of electrodes.

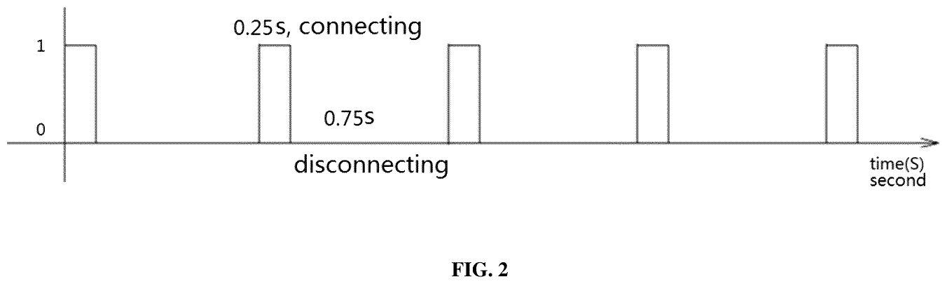

The second control method and logic are that the chopper buck circuit is in the normally on state (i.e., not bucking), and the pulse-width modulation and driver circuit controls the turn-on and turn-off of Gn, which is determined by the ratio of the rated voltage of the power supply and the transient voltage. For example, when the voltage is reduced by 50%, 50% of the electrodes will be disconnected from the power supply, and the other 50% of the electrodes and the power supply in the on state, but this time the on state is not a “constant on” state, but through the pulse width modulation circuit “duty cycle “control” on the ‘on rate’, the duty cycle ratio is equal to the transient current and rated current ratio of the same. Such as transient current and rated current ratio of ¼, the pulse width modulation duty cycle of 25%, due to the special requirements of the electrolytic tank, the duty cycle of the frequency from a few Hertz to dozens of Hertz, otherwise the electrode response will lag. As shown in FIG. 2 for a duty cycle of 25%, 1 is on, 0 is not on, such as FIG. 2.

The present invention is further illustrated by the following examples.

### Example 1

Select a rated power of 100 kW wind turbine, its generator is three-phase permanent magnet generator, the generator rated voltage is 110 volts, rated wind speed is 12 m/s, the generator output through the rectifier connected in parallel to the DC busbar as the power supply of electrolyzer. The following table shows the power output characteristics of the wind turbine at different wind speeds.

| Wind (m/s) | Vac | Vdc | Idc | Power(Watt) |
|---|---|---|---|---|
| 12 | 110 | 146.3 | 683.5 | 100,000 |
| 11.5 | 105.4 | 140.2 | 627.8 | 88,014 |
| 11 | 100.8 | 134.1 | 574.4 | 77,025 |
| 10.5 | 96.3 | 128 | 523.3 | 66,992 |
| 10 | 91.7 | 121.9 | 474.7 | 57,870 |
| 9.5 | 87.1 | 115.8 | 428.4 | 49,617 |
| 9 | 82.5 | 109.7 | 384.5 | 42,188 |
| 8.5 | 77.9 | 103.6 | 343 | 35,540 |
| 8 | 73.3 | 97.5 | 303.8 | 29,630 |
| 7.5 | 68.8 | 91.4 | 267 | 24,414 |
| 7 | 64.2 | 85.3 | 232.6 | 19,850 |
| 6.5 | 59.6 | 79.2 | 200.5 | 15,893 |
| 6 | 55 | 73.2 | 170.9 | 12,500 |
| 5.5 | 50.4 | 67.1 | 143.6 | 9,628 |
| 5 | 45.8 | 61 | 118.7 | 7,234 |
| 4.5 | 41.3 | 54.9 | 96.1 | 5,273 |
| 4 | 36.7 | 48.8 | 75.9 | 3,704 |
| 3.5 | 32.1 | 42.7 | 75.9 | 3,241 |
| 3 | 27.5 | 36.6 | 75.9 | 2,778 |
| 2.5 | 23 | 30.5 | 75.9 | 2,315 |
| 2 | 18.4 | 24.4 | 75.9 | 1,852 |

In Example 1, the wind speed is reduced from the rated wind speed of 12 m/s to 6 m/s. Since the energy of the wind is cubically related to the wind speed, when the wind speed is reduced from 12 m/s to 6 m/s, the output power of the wind turbine is reduced to ⅛ of the rated power, and correspondingly, the voltage is reduced to ½ of the rated voltage, and the current is reduced to ¼ of the rated current, i.e., the voltage is reduced by half of the original, and the current is reduced by by a factor of 4, and the power is reduced by a factor of 8.

If the first control method and logic are used, the ratio of the rated current to the transient current is 4, and the voltage reduction multiplier is 4, then the current will be increased by a factor of 4 on top of the transient current and become a constant current source. The constant current source control circuit Gn to Gn⅞ of the electrode and the power supply is disconnected, only G2 to Gn⅛ of the electrode (rounded) and the power supply is on, due to the voltage of the power supply itself is reduced by half, coupled with the buck circuit to achieve a 4-times reduction in the actual output voltage is only the rated voltage of ⅛, so that the electrode in the state of ⅛ of the on state is always in the constant current source and rated voltage The electrode of ⅞ is completely disconnected from the power supply.

If the second control method and control logic is used, the chopper buck circuit is in a normally-conducting state (i.e., not bucking), and Gn in the constant-current source control circuit is determined to be either disconnected or on from Gn to G2 according to the ratio relationship between the transient voltage and the rated voltage, but the duty cycle of the electrodes that conduct at this point in time is determined by the ratio of the transient current and the rated current. As in this embodiment, when the wind speed is reduced by 50% and the voltage is also reduced by 50%, the electrodes from Gn to Gn/2 (rounded up) are in the disconnected state, and the electrodes from G2 to G(n−1)/2 (rounded up) are in the on state, but the on state at this time is not a “constant on” state but is in the “intermittent” state. “This “intermittency” can be expressed by the power electronics term “duty cycle”, which is determined by the ratio of the transient current to the rated current. The ratio of the duty cycle is determined by the ratio of the transient current to the rated current. In this embodiment, the ratio of the transient current to the rated current is ¼, and the duty cycle of Gn is controlled to be 25%, i.e., among 50% of the electrodes in the on-state, only ¼ of the time period is connected to the power supply and the other ¾ of the time period is disconnected from the power supply (FIG. 2), i.e., it is realized that the flow rate is the same for a certain period of time and becomes a constant-current source by time control, and the other 50% of the electrodes and the power supply are in a completely disconnected state. The other 50% of the electrodes and power supply are completely disconnected.

### Example 2

It is the same wind turbine. When the wind speed reduces from 12 m/s to 4 m/s, the generator voltage was reduced by a factor of 3 from 146.3 volts to 48.8 volts, the generator current was reduced by a factor of 9 from 683.5 amps to 75.9 amps, and the power was reduced by a factor of 27.

If the first control method and logic is used, the current drops by a factor of 4, the ratio of the rated current to the transient current is 9, and the step-down circuit reduce multiplier is 9. The current value is boosted by 9-times by the chopper buck circuit, which keeps the current to the constant current source state of 683.5 amperes. At the same time, because the power is reduced by 27 times, only 1/27 of the electrodes from Gn to G2 are in a constant on state with the power supply (taking an integer value), and 26/27 of the electrodes are in an off state with the power supply, so that the voltage and current of the power supply are always matched with the power of the electrodes in the electrolytic cell in the working state.

If the second control method and control logic is used, the voltage reduction circuit is in the state of constant conduction (i.e., no voltage reduction), and Gn in the control circuit of the constant-current source determines the disconnection or conduction of Gn to G2 according to the ratio relationship between the transient voltage and the rated voltage. In this example, the voltage is reduced by a factor of 3, ⅔ of the electrodes and the power supply are disconnected (rounding down), and only ⅓ of the electrodes and the power supply are in the “intermittent” conduction state. The duty cycle of the intermittent conduction state is 1/9 (11.1%), that is, among the ⅓ electrodes in the working state, only 11.1% of the time period is in the conduction state, and 88.9% of the time period is in the non-conducting state, which ensures that each electrode is in the state of stable operation under the state of constant-current and rated-voltage in the production of hydrogen. That is, the power applied to the electrodes of working is a pulsed power of equal amplitude. The working electrodes will work stable under rated voltage.

As illustrated by the above two examples, through the method of turning on or off the electrodes by voltage reduction and selection according to the voltage ratio as well as the method of selecting the intermittent turn-on of the electrodes by the duty cycle, it is possible to keep the working state of the electrodes of the electrolyzer to always work stably in the state of constant current source and rated voltage. Meanwhile, through the above two exemplary embodiments, it can be clearly understood that the control method and control logic of the present invention is to keep each electrode in stable operation under the rated voltage and constant current source state when the rated wind speed is below the rated wind speed or when the light intensity is insufficient.

The present invention is a fusion innovation based on a full understanding of the characteristics of the wind energy, solar energy and electrolysis with very large energy fluctuations, and has high market value and industrial adaptability.

The above mentioned methods are only representative embodiments of the control mode and control logic in the present invention. All changes and combinations of electrodes and electrolyzers made in accordance with the control mode and logic of the present invention shall be within the scope of the present invention, such as connecting a control switch to the first electrode as well but making the control switch in the state of being normally disconnected.

I claim:

1. An adaptive variable cycle electrolysis control device, comprising
an adaptive variable cycle power control device being connected in series between an electrolysis tank and a power source during electrochemical electrolysis,
wherein the adaptive variable cycle power control device comprises
a voltage-relief circuit,
a pulse-width modulation and drive circuit, and
a constant-current source control circuit,
wherein an output of the voltage-relief circuit is connected to an input of the constant-current source control circuit,
each of outputs of the constant-current source control circuit is respectively connected to each of electrodes of the electrolysis tank,
each electrode comprises a contact that is connected in series with each electrode through a contact control switch (Gn),
the pulse width modulation and drive circuit controls turn-on and turn-off of the voltage-relief circuit and the constant-current source control circuit, respectively.

2. The adaptive variable cycle electrolysis control device according to claim 1, wherein each electrode in the electrolysis tank comprises a contact,
each output of the constant-current source control circuit is respectively connected in series to an electrode through a contact control switch (Gn), and
the power source is a renewable energy power supply source.

3. The adaptive variable cycle electrolysis control device according to claim 2, wherein a number of electrodes of the electrolysis tank is selected according to a maximum output voltage value of a fluctuating power supply,
a first electrode is connected to a negative pole of the power supply,
a number of outputs of the constant-current source control circuit is one less than the number of electrodes, and
a nth output of the constant current source is connected to a nth electrode.

4. A method for controlling the adaptive variable cycle electrolysis control device as described in claim 2, comprising
(1) providing a ratio of a voltage drop of the voltage reduction circuit as same as a ratio of a rated current of the renewable energy power supply to an instantaneous current, and adjusting the voltage drop value by a duty cycle of the voltage reduction circuit;
(2) connecting or disconnecting the individual outputs and contacts in the constant power control circuit in accordance with a ratio of an instantaneous power value and a rated power value of the renewable energy power supply, and determining the contact control switch (Gn) to be turned on or off.

5. A method for controlling the adaptive variable cycle electrolysis control device according to claim 2, comprising
(1) when the contact control of the voltage-relief circuit is in a normally-conducting status, determining turn-on or turn-off of Gn in the constant-current source control circuit according to a ratio of a value of an instantaneous voltage of a power supply of the renewable energy source to a value of a rated voltage;
(2) according to a ratio of an instantaneous current to a rated current of the input power supply, causing the contacts in the constant-current source control circuit that are in an on status are in a transient on and a transient off status.

6. The method according to claim 4, wherein a turned-on state of the contact control switch (Gn) is normally on or normally off.

7. The method according to claim 5, wherein the transient on and off time ratio is determined according to a ratio of a transient current and the rated current of the renewable energy supply power source.

8. The adaptive variable cycle electrolysis control device according to claim 1, wherein the pulse width modulation and drive circuit uses a modulating wave frequency of a duty cycle at a range between 5 Hz to 50 Hz.

9. An electrolysis station, comprising
a plurality of the adaptive variable cycle electrolysis control devices as described in claim 1 connected in parallel.
